(19) United States
(12) Patent Application Publication
(10) Pub. No.: US 2016/0126505 A1
(43) Pub. Date: May 5, 2016

(54) Solution Process Electron Transporting Layer for Polymer Light Emitting Diode

(71) Applicant: Nano and Advanced Materials Institute Limited, Hong Kong (HK)

(72) Inventors: Tsang Ming Michael CHOI, Hong Kong (HK); Tsz Kiu Brian LO, Hong Kong (HK); Kwok Keung Paul HO, Hong Kong (HK)

(21) Appl. No.: 14/527,792

(22) Filed: Oct. 30, 2014

(51) Int. Cl. H01L 51/56; H01L 51/00; H01L 51/52

(52) U.S. Cl. CPC H01L 51/56; H01L 51/5215; H01L 51/5221; H01L 51/0003; H01L 51/0005; H01L 51/0026; H01L 51/0072; H01L 51/007; H01L 51/0067; H01L 2251/301; H01L 2251/308; H01L 51/5072

(57) ABSTRACT

The present invention relates to a method for fabricating a solution-processed PLED including an electron transport layer. The electron transport layer, deposited on an emission layer by a solution process, provides the performance comparable to those processed by vacuum deposition. In addition, the method of the present invention is able to lower manufacturing cost and reduce time for fabrication.

### COPYRIGHT NOTICE

A portion of the disclosure of this patent document contains material, which is subject to copyright protection. The copyright owner has no objection to the facsimile reproduction by anyone of the patent document or the patent disclosure, as it appears in the Patent and Trademark Office patent file or records, but otherwise reserves all copyright rights whatsoever.

### FIELD OF THE INVENTION

The present invention relates to a polymer light emitting diode. More particularly, the present invention relates to a method for fabricating a polymer light emitting diode by depositing a thin layer of electron transport layer (ETL) by solution process.

### BACKGROUND

Recently the development of polymer light-emitting diodes (PLED) focuses on enhancing the device efficiency and operating lifetime by multilayer device structure. In the multilayer PLED, electron transport layer (ETL) plays an important role that can provide efficient electron transport, reduce the potential barrier between the emission layer (EML) and the cathode, and prevent the cathode quenching effect by hole-blocking.

In addition, if there is no ETL, the device needs low work function or unstable cathodes, like Ca, Ba, or CsF/Al. That is one of the reasons why the lifetime of PLED is less than that of small molecular organic light-emitting diodes. The cathode LiF/Al, which is commonly used in small molecular organic light-emitting diodes, is know to be more stable than the low work function cathodes in PLED. Thus, the ETL plays an important role to provide attractive performance towards the PLED.

Concerning the fabrication of PLED, solution process is low-cost and more price-competitive than the high-cost thermal evaporation. Despite of some reports about solution-processed PLED, the dissolution problem between layers still exists in conventional solution-processed multilayer PLED, leading to mixing the layers together, and the device failing to function. Therefore, the ETL needs to be deposited by thermal evaporation.

Consequently, there is an unmet need to have a time-efficient and cost-effective manufacturing method to fabricate a PLED.

### SUMMARY OF THE INVENTION

A first aspect of the presently claimed invention is to provide a method for fabricating a polymer light emitting diode.

In accordance with an embodiment of the presently claimed invention, a method for fabricating a polymer light emitting diode comprising: providing an emission layer (EML); dissolving at least one electron transport layer (ETL) material into an alcoholic solvent to form an ETL solution; coating the ETL solution on the EML by a first solution process to form an ETL wet film; and annealing the ETL wet film to form an ETL.

A second aspect of the presently claimed invention is to provide a polymer light emitting diode.

In accordance with an embodiment of the presently claimed invention, a polymer light emitting diode comprises a substrate, a hole transport layer, an emission layer, an electron transport layer, and a cathode. The electron transport layer is fabricated by a solution process.

The present invention provides a solution-processed PLED fabrication method, which is low-cost and time-efficient during manufacturing. More importantly, the method can avoid the dissolution problem existed between the emission layer and the electron transport layer, thus providing better performance in terms of lifetime and brightness.

### BRIEF DESCRIPTION OF THE DRAWINGS

Embodiments of the present invention are described in more detail hereinafter with reference to the drawings, in which:

FIG. 1 is a schematic diagram showing a PLED according to an embodiment of the presently claimed invention;

FIG. 2 shows a schematic energy profile of the multilayer device structure of a PLED according to an embodiment of the presently claimed invention;

FIG. 3 is a flow chart showing the steps of a method for fabricating a PLED according to an embodiment of the presently claimed invention;

FIG. 4A is a graph showing a brightness curve of a blue PLED according to Example 1 of the presently claimed invention;

FIG. 4B is a graph showing a brightness curve of a green PLED according to Example 2 of the presently claimed invention;

FIG. 4C is a graph showing a brightness curve of a red PLED according to Example 3 of the presently claimed invention; and

FIG. 4D is a graph showing a brightness curve of a white PLED according to Example 4 of the presently claimed invention.

### DETAILED DESCRIPTION OF PREFERRED EMBODIMENTS

In the following description, a PLED, and methods for fabricating the PLED are set forth as preferred examples. It will be apparent to those skilled in the art that modifications, including additions and/or substitutions, may be made without departing from the scope and spirit of the invention. Specific details may be omitted so as not to obscure the invention; however, the disclosure is written to enable one skilled in the art to practice the teachings herein without undue experimentation.

In the present invention, a solution-processed PLED including the ETL is fabricated that provides performance comparable to the one prepared by conventional vacuum deposition.

Some common small molecular electron transport materials including 2,2′,2″-(1,3,5-benzinetriyl)-tris(1-phenyl-1-H-benzimidazole) (TPBi) can be dissolved in a polar solvent such as methanol, and the ETL can be formed by a spin coating method. The polar solvent can dissolve the electron transport materials only, but doesn't dissolve the EML. Preferably, the polar solvent is an alcoholic solvent. For example, methanol is a very weak solvent to the emissive layer such that the dissolution problem between ETL and EML is solved. For blade coating and inkjet printing, different alcoholic solvents can be further applied such as isopropanol, n-butanol, and mixed together to balance the surface tension, to obtain the better uniformity of the ETL during solvent evaporation, resulting in better performance of the layer.

FIG. 1 is a schematic diagram showing a PLED according to an embodiment of the presently claimed invention. The PLED comprises an ITO substrate 11, a hole transport layer 12, an emission layer 13, an electron transport layer 14, and a cathode 15. The hole transport layer 12 is formed on the ITO substrate 11. The emission layer 13 is formed on the hole transport layer 12. The electron transport layer 14 is formed on the emission layer 13. The cathode 15 is formed on the electron transport layer 14.

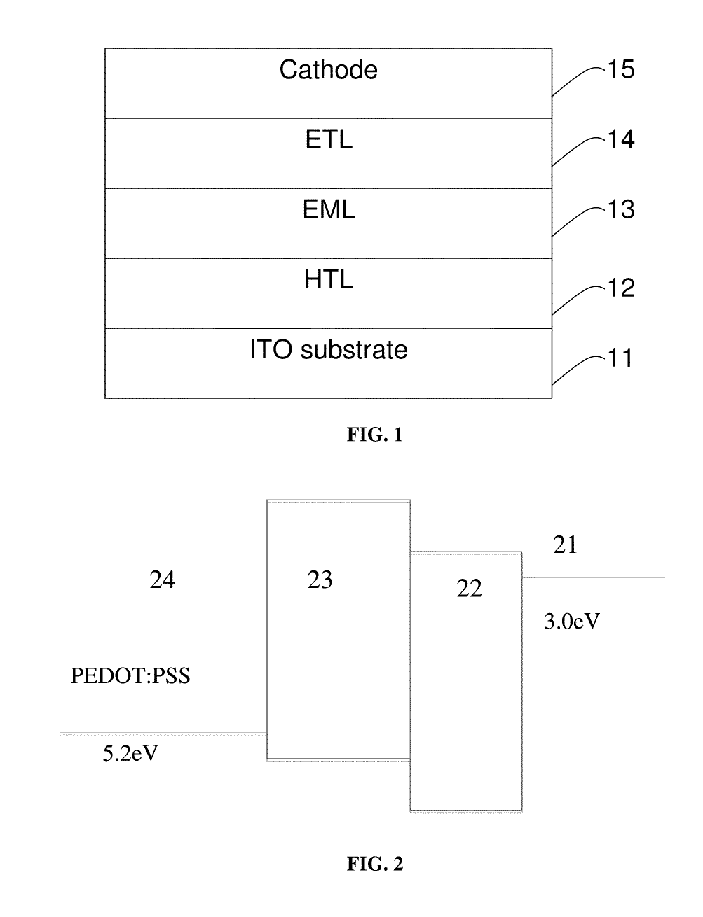

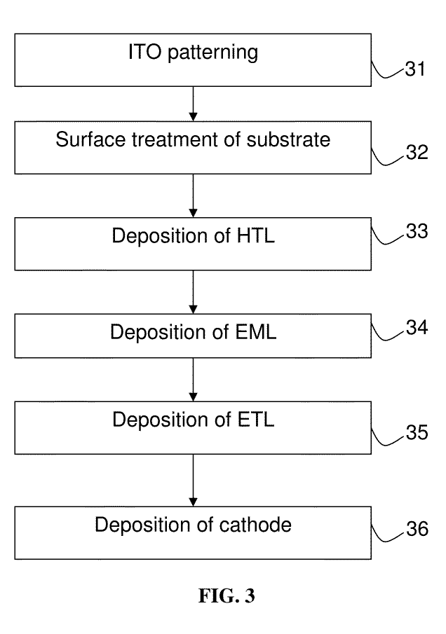

FIG. 2 shows a schematic energy profile of the multilayer device structure of a PLED according to an embodiment of the presently claimed invention. The multilayer device structure comprises a cathode 21, an ETL 22, an EML 23, and a HTL 24. The cathode 21 comprises LiF/Al, the ETL 22 comprises TPBi, and the HTL 24 comprises PEDOT:PSS. The EML 23 can comprise Poly(9-vinylcarbazole) (PVK), B is [2-(4,6-difluorophenyl)pyridinato-C²,N](picolinato)iridium(III) (FlrPic), Tris[2-phenylpyridinato-C²,N]iridium(III) (Ir(ppy)₃), or Tris[2-(4-n hexylphenyl)quinoline)]iridium(III) (Hex-Ir(pig)₃). Table 1 shows energy levels of the materials from the multilayer device structure of FIG. 2.

TABLE 1

| | |
|---|---|
| EML | ETL |

| | | | | |
|---|---|---|---|---|
| 2.2eV | 2.9eV | 2.9eV | 2.8eV | 2.7eV |
| PVK | FIrPic | Ir(ppy)₃ | Hex-Ir(piq)₃ | TPBi |
| 5.8eV | 5.7eV | 5.3eV | 4.9eV | 6.7eV |

FIG. 3 is a flow chart showing the steps of a method for fabricating a PLED according to an embodiment of the presently claimed invention. In step 31, an ITO substrate is patterned. In step 32, the surface of the ITO substrate is treated. In step 33, a HTL is deposited on the surface of the ITO substrate. In step 34, an EML is deposited on the HTL. In step 35, an ETL is deposited on the EML. In step 36, a cathode is deposited on the ETL.

Step 34 comprises the steps of dissolving an emission material in a non-polar solvent to form an EML solution, coating the EML solution on the HTL by a solution process to form an EML wet film, and annealing the EML wet film to form the EML. The non-polar solvent used therein is able to further reduce the dissolution problem during the deposition of the EML.

Preferably, the emission material comprises poly-(N-vinyl carbazole) (PVK), Poly(p-phenylene vinylene) (PPV), or spiro-bifluorene polymer. The non-polar solvent can be toluene, or chlorobenzene. The solution process can be a spin coating, an inkjet printing, or a blade coating.

Step 35 comprises the steps of dissolving an electron transport layer (ETL) material into an alcoholic solvent to form an ETL solution, coating the ETL solution on the EML by a first solution process to form an ETL wet film, and annealing the ETL wet film to form an ETL. As the solution process is used, instead of thermal evaporation, the method of the present invention is more cost-effective and time-efficient.

Preferably, the ETL material includes 2,2′,2″-(1,3,5-benzinetriyl)-tris(1-phenyl-1-H-benzimidazole) (TPBi), 2(4-biphenyl)-5-(4-tert-butylphenyl)-1,3,4-oxdiazole (PBD), or 3-(4-biphenyl)-4-phenyl-5-tert-butylphenyl-1,2,4-triazole (TAZ). The alcoholic solvent is selected from the group consisting of methanol, isopropanol, n-butanol, ethylene glycol and combinations thereof. The choice and mixing of the alcoholic solvents depend on the solubility of the ETL material used. Preferably, a volume ratio of an alcoholic solvent mixture is 95% of methanol, 4.5% of n-butanol, and 0.5% of ethylene glycol. The alcoholic solvent mixture can avoid the coffee ring effect and assist in preparing a smooth, even thin film.

The ETL solution comprises 0.2-1 wt % of the ETL material. The ETL material can be small molecule based.

Preferably, the step of annealing the ETL wet film to form the ETL layer is performed at 90-120° C. for 5-15 min. The solution process can be a spin coating, an inkjet printing, or a blade coating. The ETL layer comprises a thickness from 10 to 40 nm.

Preferably, a spin coating rate is about 2-4000 rpm, depending on the required thickness. For example, for 0.5 wt % of TPBi, 2500 rpm is used to produce a TPBi layer with 10 nm.

As the non-polar solvent used in step 34 is not dissolved in the alcoholic solvent used in step 35, the dissolution problem between the EML and ETL is avoided.

### Example 1

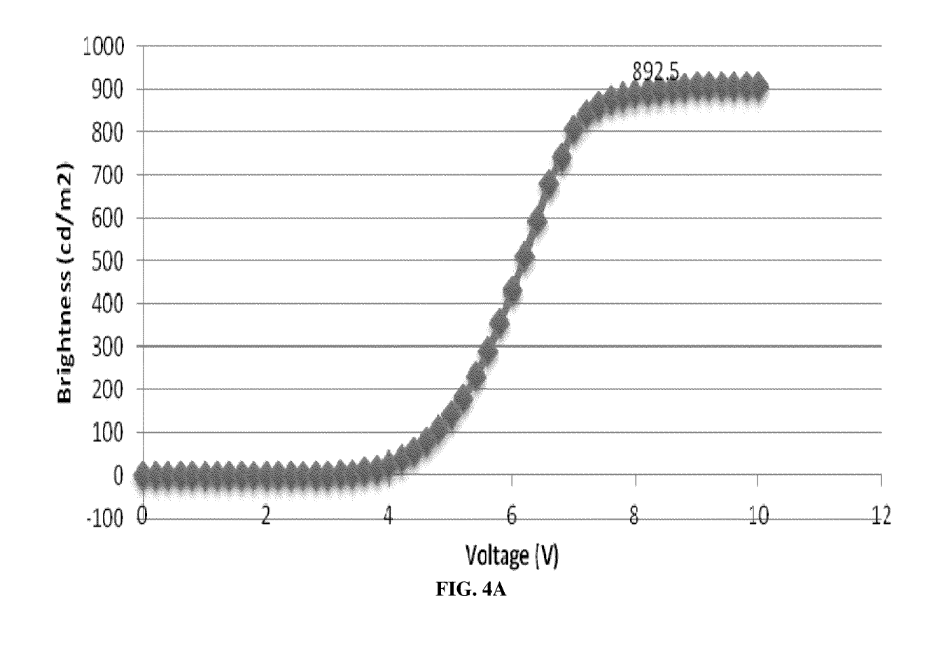

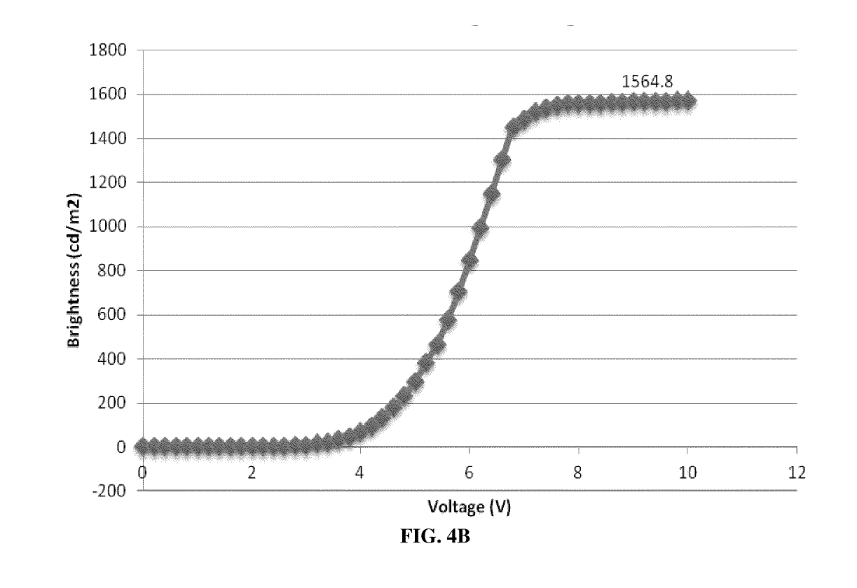

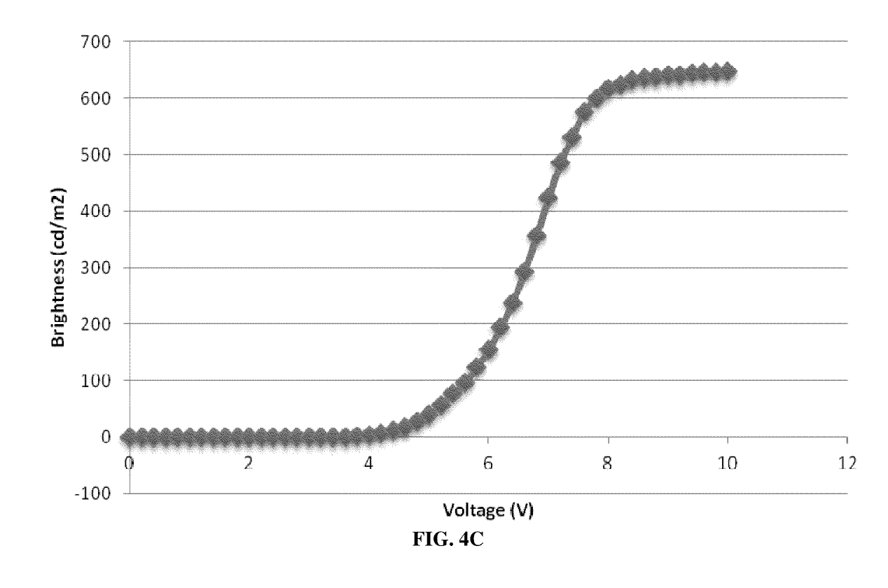

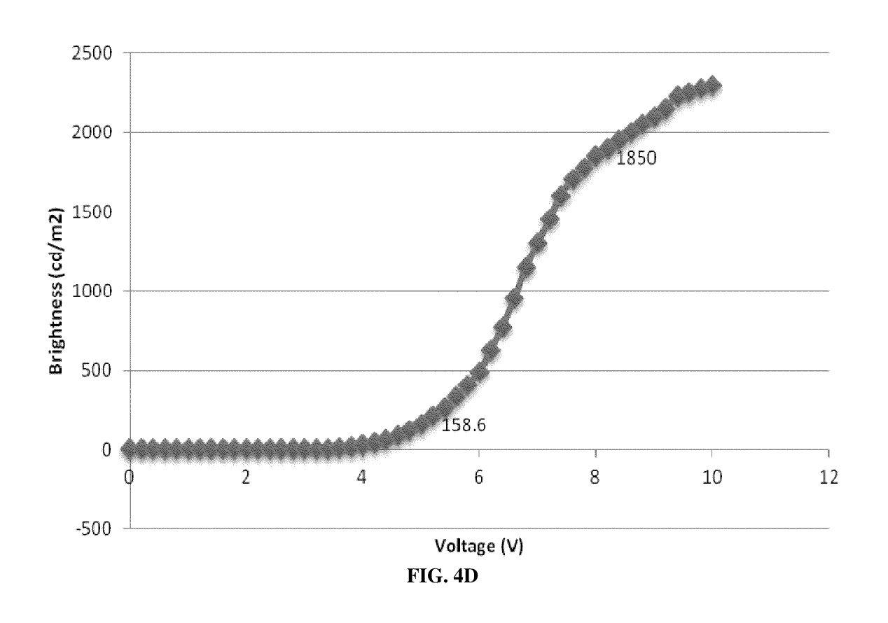

A blue PLED was fabricated according to an embodiment of the presently claimed invention. The blue PLED comprised a multi-layered structure of ITO/MoO₃ (10 nm)/blue EML: 10% FirPIc in PVK (25 nm)/TPBi (10 nm)/Al (150 nm). The TPBi of ETL layer was deposited by a spin coating, and annealed at 100° C. for 10 min. FIG. 4A shows a brightness curve of the blue PLED at different voltages. The brightness of the blue LED is plotted versus voltage. The highest brightness of the blue LED is 892.5 cd/m².

### Example 2

A green PLED was fabricated according to an embodiment of the presently claimed invention. The green PLED comprised a multi-layered structure of ITO/MoO₃ (10 nm)/green EML: 10% Ir(ppy)3 in PVK (25 nm)/TPBi (10 nm)/Al (150 nm). The TPBi of ETL layer was deposited by a spin coating, and annealed at 100° C. for 10 min. FIG. 4B shows a brightness curve of the green PLED at different voltages. The brightness of the green LED is plotted versus voltage. The highest brightness of the blue LED is 1564.8 cd/m².

### Example 3

A red PLED was fabricated according to an embodiment of the presently claimed invention. The red PLED comprised a multi-layered structure of ITO/MoO₃ (10 nm)/red EML: 10% hex-Ir(piq)3 in PVK (25 nm)/TPBi (10 nm)/Al (150 nm). The TPBi of ETL layer was deposited by a spin coating, and annealed at 100° C. for 10 min. FIG. 4C shows a brightness curve of the red PLED at different voltages. The brightness of the red LED is plotted versus voltage. The highest brightness of the blue LED is about 640 cd/m².

### Example 4

A white PLED was fabricated according to an embodiment of the presently claimed invention. The white PLED comprised a multi-layered structure of ITO/MoO₃ (10 nm)/white EML: spiro-bifluorene copolymer (50 nm)/TPBi (10 nm)/Al (150 nm). The TPBi of ETL layer was deposited by a spin coating, and annealed at 100° C. for 10 min. FIG. 4D shows a brightness curve of the white PLED at different voltages. The brightness of the white LED is plotted versus voltage. The highest brightness of the blue LED is about 2300 cd/m².

A lifetime test was conducted with a PLED of the present invention. After working for more than 2000 hr, the brightness of the PLED was only dropped by 50%, indicating that even using a cost effective solution process, the performance of the PLED of the present invention is still guaranteed.

The foregoing description of the present invention has been provided for the purposes of illustration and description. It is not intended to be exhaustive or to limit the invention to the precise forms disclosed. Many modifications and variations will be apparent to the practitioner skilled in the art.

The embodiments were chosen and described in order to best explain the principles of the invention and its practical application, thereby enabling others skilled in the art to understand the invention for various embodiments and with various modifications that are suited to the particular use contemplated. It is intended that the scope of the invention be defined by the following claims and their equivalence.

1. A method for fabricating a polymer light emitting diode comprising:
providing an emission layer (EML);
dissolving at least one electron transport layer (ETL) material into at least one alcoholic solvent to form an ETL solution;
coating the ETL solution on the EML by a first solution process to form an ETL wet film; and
annealing the ETL wet film to form an ETL.

2. The method of claim 1, wherein the ETL material includes 2,2′,2″-(1,3,5-benzinetriyl)-tris(1-phenyl-1-H-benzimidazole) (TPBi), 2(4-biphenyl)-5-(4-tert-butylphenyl)-1,3,4-oxdiazole (PBD), or 3-(4-biphenyl)-4-phenyl-5-tert-butylphenyl-1,2,4-triazole (TAZ).

3. The method of claim 1, wherein the alcoholic solvent is selected from the group consisting of methanol, isopropanol, n-butanol, ethylene glycol and combinations thereof.

4. The method of claim 1, wherein the alcoholic solvents form an alcoholic solvent mixture comprising a volume ratio of 95% of methanol, 4.5% of n-butanol, and 0.5% of ethylene glycol.

5. The method of claim 1, wherein the ETL material is small molecule based.

6. The method of claim 1, wherein the ETL solution comprises 0.2-1 wt % of the ETL material.

7. The method of claim 1, wherein the step of annealing the ETL wet film to form the ETL is performed at 90-120° C. for 5-15 min.

8. The method of claim 1, wherein the first solution process is a first spin coating, a first inkjet printing, or a first blade coating.

9. The method of claim 8, wherein the first spin coating comprises a spin coating rate in a range of 2 to 4000 rpm.

10. The method of claim 1, wherein the ETL comprises a thickness ranged from 10 to 40 nm.

11. The method of claim 1, wherein the step of forming the EML comprises:
dissolving at least one emission material in a non-polar solvent to form an EML solution;
coating the EML solution on a hole transport layer by a second solution process to form an EML wet film; and
annealing the EML wet film to form the EML.

12. The method of claim 11, wherein the emission material comprises poly-(N-vinyl carbazole) (PVK), poly(p-phenylene vinylene) (PPV), or spiro-bifluorene polymer.

13. The method of claim 11, wherein the non-polar solvent comprises toluene, or chlorobenzene.

14. The method of claim 11, wherein the second solution process is a second spin coating, a second inkjet printing, or a second blade coating.

15. The method of claim 1, further comprising:
providing a substrate;
forming a hole transport layer (HTL) on the substrate;
forming the EML on the hole transport layer; and
forming a cathode on the ETL layer.

16. The method of claim 15, wherein the substrate comprises indium tin oxide, and the cathode comprises lithium fluoride/aluminum.

17. A polymer light emitting diode, fabricated by the method of claim 1.
